(19) United States
(12) Patent Application Publication
(10) Pub. No.: US 2025/0210374 A1
(43) Pub. Date: Jun. 26, 2025

(54) METHODS AND STRUCTURES FOR IMPROVING ETCH PROFILE OF METALLIC LAYER

(71) Applicant: Tokyo Electron Limited, Tokyo (JP)

(72) Inventors: Christopher CATANO, Albany, NY (US); Brandon BYRNS, Albany, NY (US); Matthew REDNOR, Albany, NY (US); Jeffrey SHEARER, Albany, NY (US)

(73) Assignee: Tokyo Electron Limited, Tokyo (JP)

(21) Appl. No.: 18/391,331

(22) Filed: Dec. 20, 2023

(51) Int. Cl. H01L 21/3213; H01L 21/033; H01L 21/311

(52) U.S. Cl. CPC H01L 21/32139; H01L 21/0332; H01L 21/31116

(57) ABSTRACT

A method for fabricating semiconductor devices is disclosed. The method includes sequentially forming at least a first hardmask layer and a second hardmask layer over a metallic layer. The method includes patterning the second hardmask layer and then the first hardmask layer. The method includes oxidizing a sidewall of the patterned first hardmask layer. The method includes removing the oxidized sidewall of the first hardmask layer. The method includes etching the metallic layer using a remaining portion of the first hardmask layer as a mask.

### FIELD OF THE DISCLOSURE

This disclosure generally relates to methods for fabricating semiconductor devices/structures, and more particularly to trimming a dielectric hardmask layer using an ion-free etchant gas for improving an etched profile.

### BACKGROUND

In the manufacture of a semiconductor device, various fabrication processes are executed such as film-forming depositions, etch mask creation, patterning, material etching and removal, and doping treatments. These processes are performed repeatedly to form desired semiconductor device elements on a substrate. While semiconductor devices have scaled down with their feature sizes decreased and aspect ratios increased, such scaling efforts are running into greater challenges as scaling enters single digit nanometer semiconductor device fabrication processes. Although nanoscale semiconductor fabrication processes have been successfully demonstrated and implemented, various embodiments can include numerous operations, and may include increasing stability of semiconductor device element or features.

### SUMMARY

One aspect of the present disclosure is directed to a method for fabricating semiconductor devices. The method includes sequentially forming at least a first hardmask layer and a second hardmask layer over a metallic layer. The method includes patterning the second hardmask layer and then the first hardmask layer. The method includes oxidizing a sidewall of the patterned first hardmask layer. The method includes removing the oxidized sidewall of the first hardmask layer. The method includes etching the metallic layer using a remaining portion of the first hardmask layer as a mask.

In some embodiments, the step of removing the oxidized sidewall of the first hardmask layer includes flowing an etchant gas. The step of removing the oxidized sidewall of the first hardmask layer is ion-free.

In some embodiments, the first hardmask layer includes a dielectric material selected from the group consisting of: silicon nitride (SiN), silicon oxynitride (SiON), silicon nitride-based material, and combinations thereof, and the second hardmask layer includes a metal oxide material.

In some embodiments, prior to etching the metallic layer, the method further includes repeating the step of oxidizing a sidewall of the patterned first hardmask layer and the step of removing the oxidized sidewall of the first hardmask layer.

In some embodiments, subsequently to etching the metallic layer, the method further includes repeating the step of oxidizing a sidewall of the patterned first hardmask layer and the step of removing the oxidized sidewall of the first hardmask layer. Subsequently to repeating the step of oxidizing a sidewall of the patterned first hardmask layer and the step of removing the oxidized sidewall of the first hardmask layer, the method further includes etching again the metallic layer.

In some embodiments, prior to forming the first hardmask layer, the method includes covering the metallic layer with a third hardmask layer comprising an organic dielectric.

In some embodiments, the remaining portion of the first hardmask layer has a first dimension and the patterned second hardmask layer has a second dimension, and wherein the first dimension is smaller than the second dimension.

Another aspect of the present disclosure is directed to a method for fabricating semiconductor devices. The method includes forming a first hardmask layer over a metallic layer. The method includes forming a second hardmask layer over the first hardmask layer. The method includes performing a first etching process to pattern the first hardmask layer through the second hardmask layer, thereby exposing a sidewall of the patterned first hardmask layer. The method includes removing a portion of the exposed sidewall of the first hardmask layer through flowing an ion-free etchant gas. The method includes performing a second etching process using a remaining portion of the first hardmask layer as a mask to pattern the metallic layer.

In some embodiments, the removed portion of the exposed sidewall comprises an oxidized dielectric material.

In some embodiments, the first hardmask layer comprises a dielectric material selected from the group consisting of: silicon nitride (SiN), silicon oxynitride (SiON), silicon nitride-based material, and combinations thereof, and the second hardmask layer comprises a metal oxide material.

In some embodiments, prior to performing the second etching process, the method further includes repeating the step of removing a portion of the exposed sidewall of the first hardmask layer.

In some embodiments, subsequently to performing the second etching process, the method further includes repeating the step of removing a portion of the exposed sidewall of the first hardmask layer. Subsequently to repeating the step of removing a portion of the exposed sidewall of the first hardmask layer, the method further includes performing a third etching process on the metallic layer.

In some embodiments, prior to forming the first hardmask layer, the method includes covering the metallic layer with a third hardmask layer comprising an organic dielectric.

In some embodiments, the remaining portion of the first hardmask layer has a first dimension and the patterned second hardmask layer has a second dimension, and wherein the first dimension is smaller than the second dimension.

Yet another aspect of the present disclosure is directed to a method for fabricating semiconductor devices. The method includes forming a first hardmask layer over a metallic layer. The method includes forming a second hardmask layer over the first hardmask layer. The method includes performing a first etching process to pattern the first hardmask layer through the second hardmask layer. The method includes oxidizing a sidewall of the patterned first hardmask layer. The method includes removing the oxidized sidewall of the first hardmask layer through flowing an ion-free etchant gas. The method includes performing a second etching process using a remaining portion of the first hardmask layer as a mask to pattern the metallic layer.

In some embodiments, the first hardmask layer comprises a dielectric material selected from the group consisting of: silicon nitride (SiN), silicon oxynitride (SiON), silicon nitride-based material, and combinations thereof, and the second hardmask layer comprises a metal oxide material.

In some embodiments, the remaining portion of the first hardmask layer has a first dimension and the patterned second hardmask layer has a second dimension, and wherein the first dimension is smaller than the second dimension.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustrations and a further understanding of the various aspects and implementations, and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing.

FIG. 1 shows a flow chart of a method for fabricating a semiconductor structure, according to some embodiments.

FIGS. 2A-2E show cross-sectional views of a semiconductor structure, made by the method of FIG. 1, during various fabrication stages, according to some embodiments.

FIG. 3 shows a flow chart of a method for fabricating a semiconductor structure, according to some embodiments.

FIGS. 4A-4H show cross-sectional views of a semiconductor structure, made by the method of FIG. 3, during various fabrication stages, according to some embodiments.

FIGS. 5A-5E show cross-sectional views of a semiconductor structure during various fabrication stages, according to some embodiments.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

The present disclosure provides various embodiments of methods for improving an etch profile of one or more underlying metallic layers in a semiconductor device. For example, the underlying meal layer may be configured as one or more access lines (e.g., bit lines, word lines, source lines, etc.) or interconnect structures (e.g., power lines, signal lines, etc.) of the semiconductor device. In some embodiments, the disclosed methods include trimming a dielectric hardmask layer over a metallic layer using an ion-free etchant gas and then etching the metallic layer using the trimmed dielectric hard mask layer as a mask. This allows for additional hardmask margin for etching an underlying metallic layer while preventing metal from re-sputtering on the trimmed dielectric hardmask layer. Accordingly, an etch profile of the underlying metallic layer can be efficiently shrunken. The method described herein can be applied to various metal etch processes and applications, for example in fabrication processes of memory and logic devices.

Reference will now be made to the figures, which for the convenience of visualizing the fabrication techniques described herein, illustrate a variety of materials undergoing a process flow in various views. Unless expressly indicated otherwise, each Figure represents one (or a set) of fabrication steps in a process flow for manufacturing the devices described herein. In the various views of the Figures, connections between conductive layers or materials may or may not be shown. However, it should be understood that connections between various layers, masks, or materials may be implemented in any configuration to create electric or electronic circuits. When such connections are shown, it should be understood that such connections are merely illustrative and are intended to show a capability for providing such connections and should not be considered limiting to the scope of the claims.

Likewise, although the Figures and aspects of the disclosure may show or describe devices herein as having a particular shape, it should be understood that such shapes are merely illustrative and should not be considered limiting to the scope of the techniques described herein. For example, the techniques described herein may be implemented in any shape or geometry for any material or layer to achieve desired results. In addition, examples in which two transistors or devices are shown stacked on top of one another are shown for illustrative purposes only, and for the purposes of simplicity. Indeed, the techniques described herein may provide for one to any number of stacked devices. Further, although the devices fabricated using these techniques are shown as transistors, it should be understood that any type of electric electronic device may be manufactured using such techniques, including but not limited to transistors, variable resistors, resistors, and capacitors.

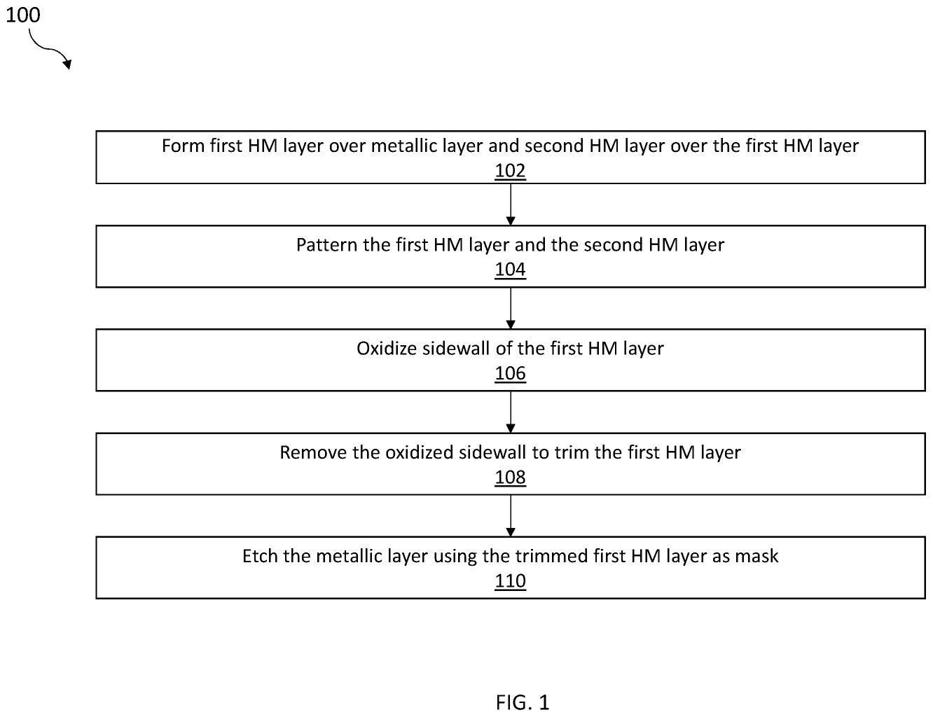

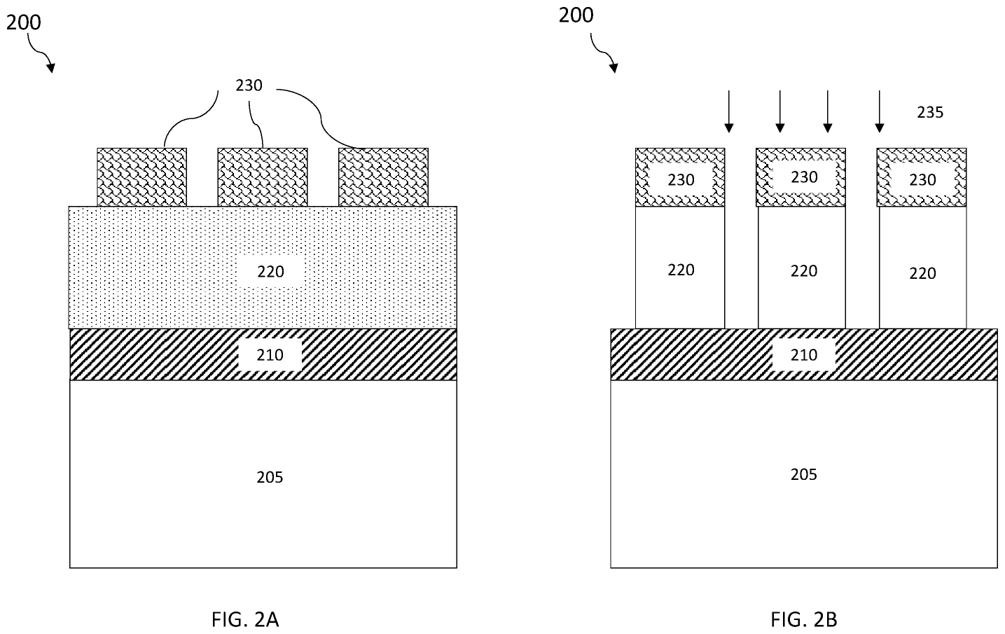

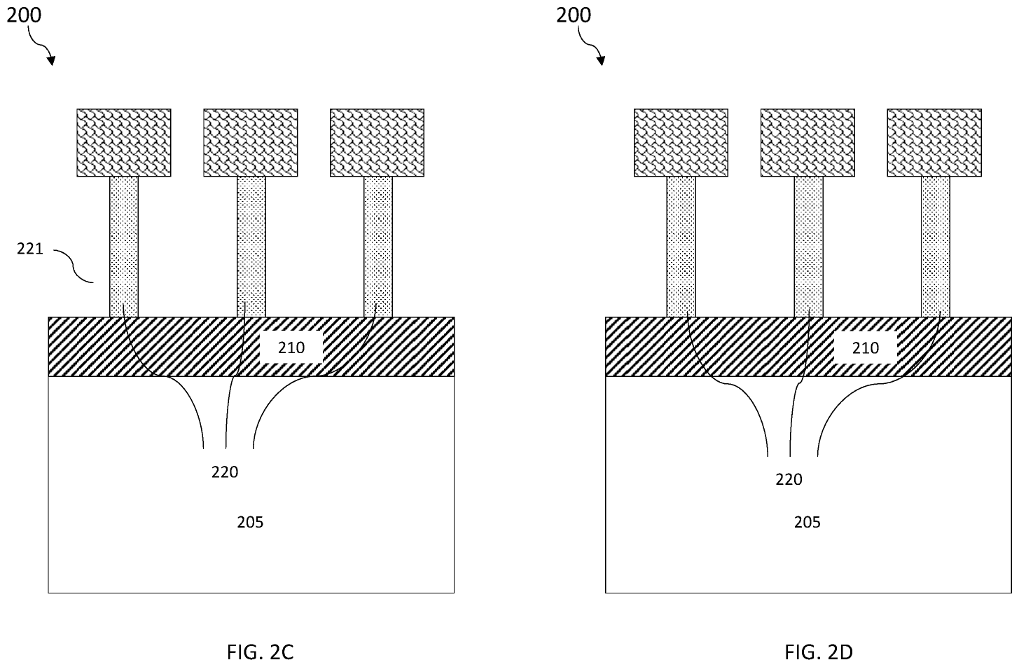

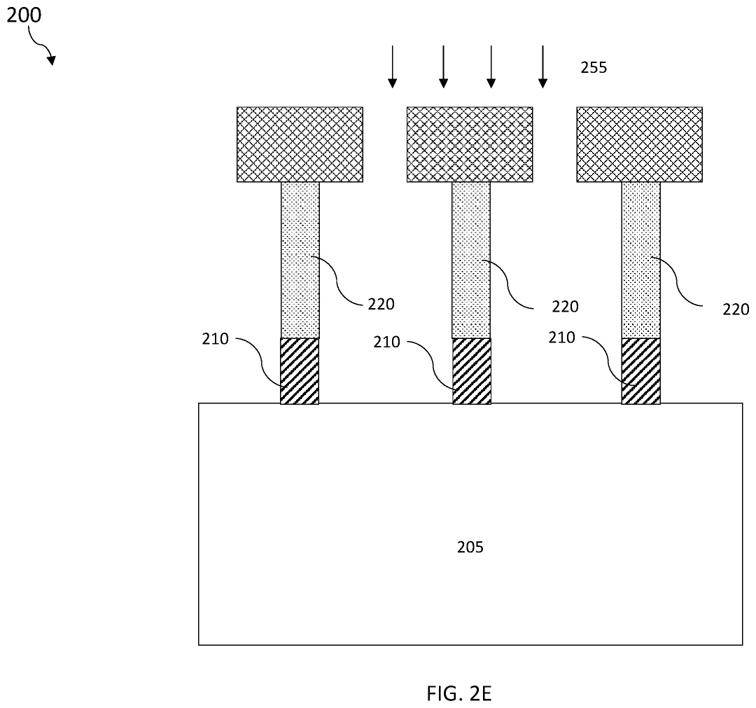

FIG. 1 illustrates a flow chart of a method 100 for fabricating a semiconductor device, in accordance with some embodiments. It is noted that the method 100 is merely an example and is not intended to limit the present disclosure. Accordingly, it is understood that additional operations may be provided before, during, and after the method 100 of FIG. 1, that any operation may be omitted, and that some other operations may only be briefly described herein. In various embodiments, operations of the method 100 may be associated with cross-sectional views of example structures at various fabrication stages as shown in FIGS. 2A to 2E, which will be discussed in further detail below. It should be understood that the structure, shown in FIGS. 2A to 2E, may include a number of other structures, while remaining within the scope of the present disclosure.

In brief overview, the method 100 starts with operation 102 of forming a first hardmask layer over a metallic layer and forming a second hardmask layer over the first hardmask layer. The method 100 continues to operation 104 of patterning the first hardmask layer through the second hardmask layer. The method 100 can proceed to operation 106 of oxidizing a sidewall of the first hardmask layer. The method 100 can proceed to operation 108 of removing the oxidized sidewall of the first hardmask layer to trim the first hardmask layer. The method 100 can proceed to operation 110 of etching the metallic layer using the trimmed first hardmask layer as a mask.

Corresponding to operation 102 of FIG. 1, FIG. 2A is a cross-sectional view of a structure 200 in which a first hardmask layer 220 is formed over a metallic layer 210, and a second hardmask layer 230 is formed over the first hardmask layer 220. The metallic layer 210, formed of one or more metal materials, may be formed over a substrate 205. The metallic layer 210 may serve as a target to be patterned based on a pattern formed in the second hardmask layer 230. The pattern in the second hardmask layer 230 can be transferred to the metallic layer 210 (e.g., to form a number of patterned segments) through the first hardmask layer 220 that is later trimmed to have a shrunken dimension. The patterned segments of the metallic layer 210 may operatively serve as access lines or interconnect structures of the structure 200, respectively.

In some embodiments, the metal materials (of the metallic layer 210) can include at least one of: ruthenium (Ru), copper (Cu), aluminum (Al), or titanium (Ti). However, it should be understood that the metallic layer 210 can be any of various compound materials that include the above-listed metal material, while remaining within the scope of the present disclosure. In some embodiments, the substrate 205 may be a semiconductor substrate, such as a bulk semiconductor, a semiconductor-on-insulator (SOI) substrate, or the like, which may be doped (e.g., with a p-type or an n-type dopant) or undoped. The substrate 205 may be a wafer, such as a silicon wafer. Other substrates, such as a multi-layered or gradient substrate may also be used. In some embodiments, the first hardmask layer 220 may include a dielectric material selected from the group consisting of: silicon nitride (SiN), silicon oxynitride (SiON), silicon nitride-based material, and combinations thereof, and the second hardmask layer 230 may include a metal oxide material such as, for example, zirconium (Zr) oxide, titanium (Ti) oxide, tungsten (W) oxide, aluminum (Al) oxide, or combinations thereof. In some other embodiments, the second hardmask layer 230 may include a metal nitride, a metal carbide, or combinations thereof.

Corresponding to operation 104 of FIG. 1, FIG. 2B is a cross-sectional view of the structure 200 in which the first hardmask layer 220 is patterned through the second hardmask layer 230. In some embodiments, the first hardmask layer 220 may be patterned through performing a directional or anisotropic etching process 235. For example, through the anisotropic etching process 235, the pattern formed in the second hardmask layer 230 can be transferred to the underlying first hardmask layer 220. In some embodiments, the anisotropic etching process 235 may be stopped upon the metallic layer 210 being exposed.

In the example where the first hardmask layer 220 is formed of SiN, the anisotropic etching process 235 may include flowing CH₃F gas with ions (or reactive ions) in presence. Further, the anisotropic etching process 235 may be a reactive ion etching (RIE) process. In general, the RIE process entails exposing a workpiece to a reactive plasma that may include gases that generate species, such as fluorine, carbon, hydrogen, and molecules and radicals of the combination of these elements. Energetic ion bombardment by species extracted from the RIE plasma can generally have a trajectory normal to a surface of the workpiece that horizontal surfaces are subject to the ion bombardment to the exclusion of other surfaces such as vertical surfaces. As a non-limiting example, a high-frequency power of about 345 Watts and a low-frequency power of about 100 Watts, a pressure of about 30 millitorr, and a flow of the etchant gas (CH₃F) of about 50 sccm may be used in the anisotropic etching process 235.

Corresponding to operation 106 of FIG. 1, FIG. 2C is a cross-sectional view of the structure 200 in which a sidewall of the first hardmask layer 220 is oxidized. In some embodiments, the sidewall of the first hardmask layer 220 may be partially formed as an oxidized layer 221 through an oxidation process. The oxidized layer 221 may surround an outer circumference of the first hardmask layer 220 that has not been oxidized and may inwardly extend from the intact (or original) sidewall of the first hardmask layer 220 into a core of the first hardmask layer 220. In some embodiments, such an oxidation process can be performed in the same chamber where operation 104 was performed by flowing oxygen. Alternatively or additionally, the oxidation process can be performed in a vacuum chamber of a gas chemical etch system that is configured to later perform a removal process (e.g., operation 108).

Corresponding to operation 108 of FIG. 1, FIG. 2D is a cross-sectional view of the structure 200 in which the oxidized sidewall of the first hardmask layer 220 (or the oxidized layer 221) is removed to trim the first hardmask layer 220. Depending on a thickness or extension of the oxidized layer 221, the first hardmask layer 220 may be trimmed to have a smaller dimension. For example, prior to the oxidation process, the first hardmask layer 220 may have a diameter of about 200 nanometers (nm) and the oxidized layer 221 may have a thickness of about 2 nm. After removing the oxidized layer 221, the first hardmask layer 220 may be trimmed to have a diameter of about 196 nm. In some embodiments, an iteration of operations 106 and 108 may be repeatedly performed until the dimension of the first hardmask layer 220 reaches a desired value.

In some embodiments, the removal process of the oxidized layer 221 may include an isotropic etching process with a sufficient etching selectivity between the oxidized layer 221 and other materials, e.g., the materials of the second hardmask layer 230, the first hardmask layer 220, and the metallic layer 210. As such, while removing the oxidized layer 221, the second hardmask layer 230 may remain substantially intact. For example, the removal process may include flowing an ion-free etchant gas. As a non-limiting example, a radio frequency-power of about 0 Watts, a pressure of about 200 millitorr, and a flow of the etchant gas (HF) of about 50 sccm may be used in the removal process.

Corresponding to operation 110 of FIG. 1, FIG. 2E is a cross-sectional view of the structure 200 in which the metallic layer 210 is patterned through the trimmed first hardmask layer 220. In some embodiments, the metallic layer 210 may be patterned through performing a directional or anisotropic etching process 255. For example, through the anisotropic etching process 255, the pattern formed in the trimmed first hardmask layer 220 can be transferred to the underlying metallic layer 210. For example, the first hardmask layer 220 is trimmed to have a smaller dimension with respect to the pattern formed in the second hardmask layer 230, and thus, the metallic layer 210 can follow the dimension of the trimmed first hardmask layer 220 to form a number of metal segments with a shrunk dimension. In some embodiments, the anisotropic etching process 255 may be stopped upon the substrate 205 being exposed. In some embodiments, after the metallic layer 210 has been patterned to have a desired profile, the remaining portions of the second hardmask layer 230 and the first hardmask layer 220 are removed.

In the example where the metallic layer 210 is formed of Ru, the anisotropic etching process 225 may include flowing Cl₂ gas with ions (or reactive ions) in presence. Further, the anisotropic etching process 255 may be a reactive ion etching (RIE) process. As a non-limiting example, a high-frequency power of about 1200 Watts and a low-frequency power of about 100 Watts, a pressure of about 50 millitorr, and a flow of the etchant gas (Cl₂) of about 60˜70 sccm may be used in the anisotropic etching process 225.

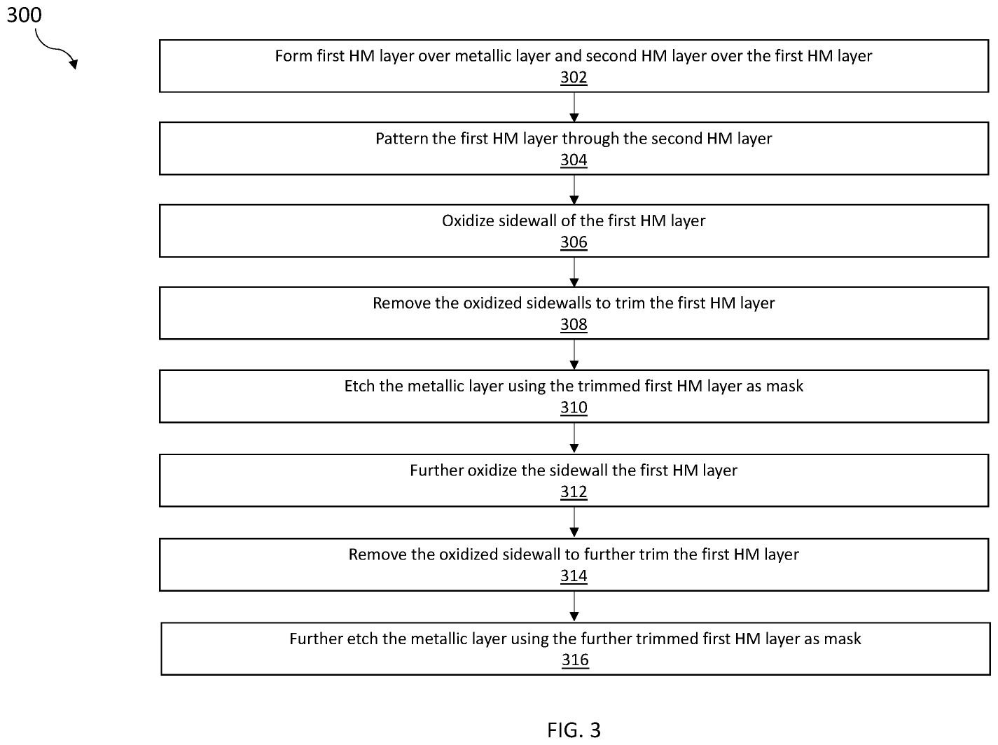

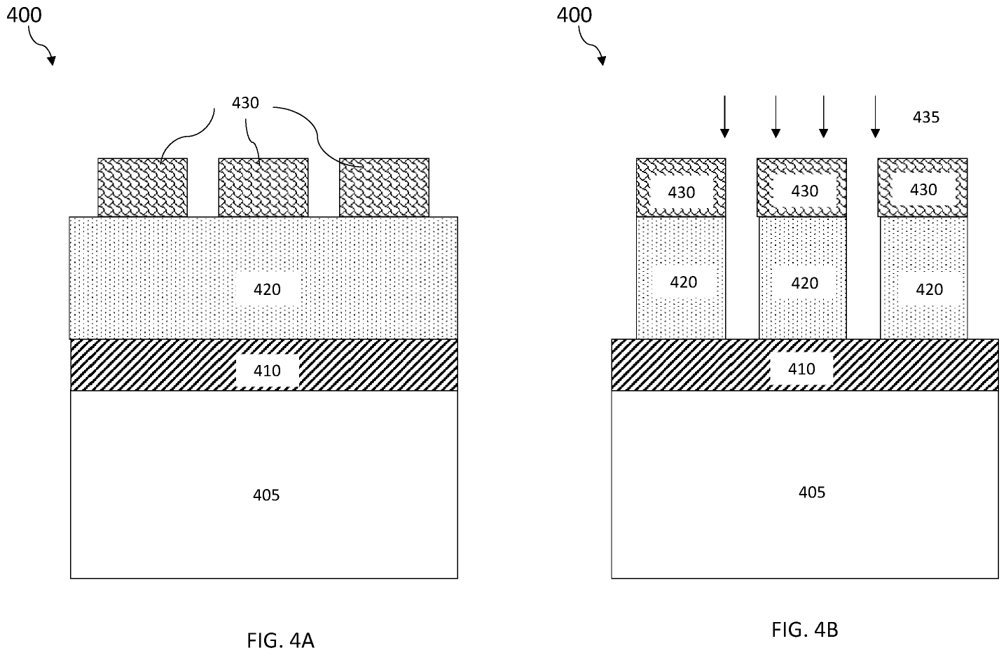

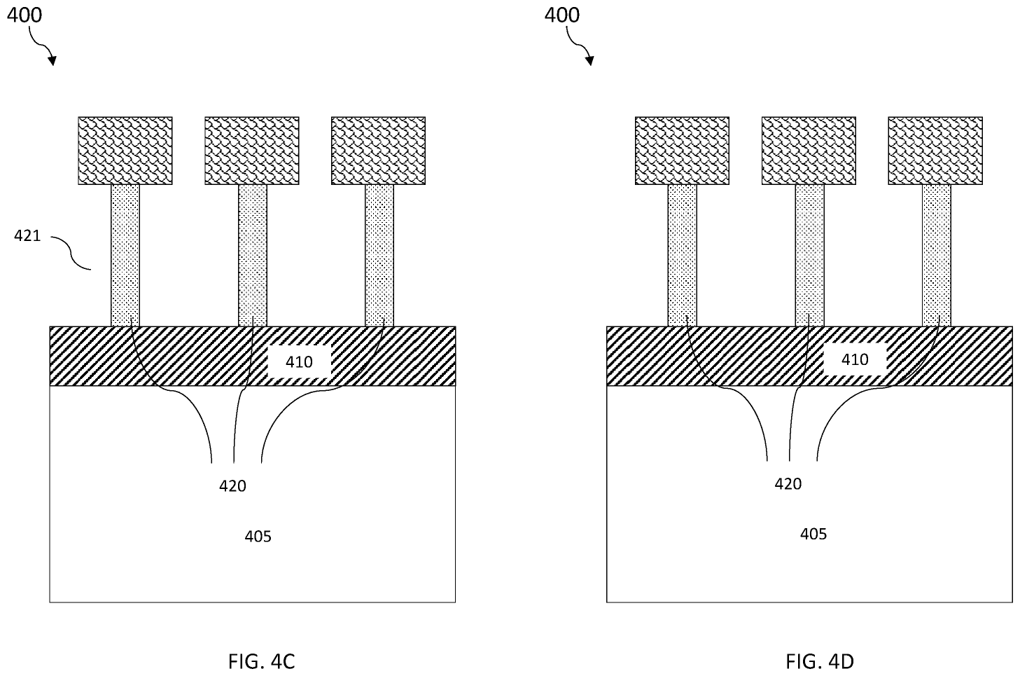

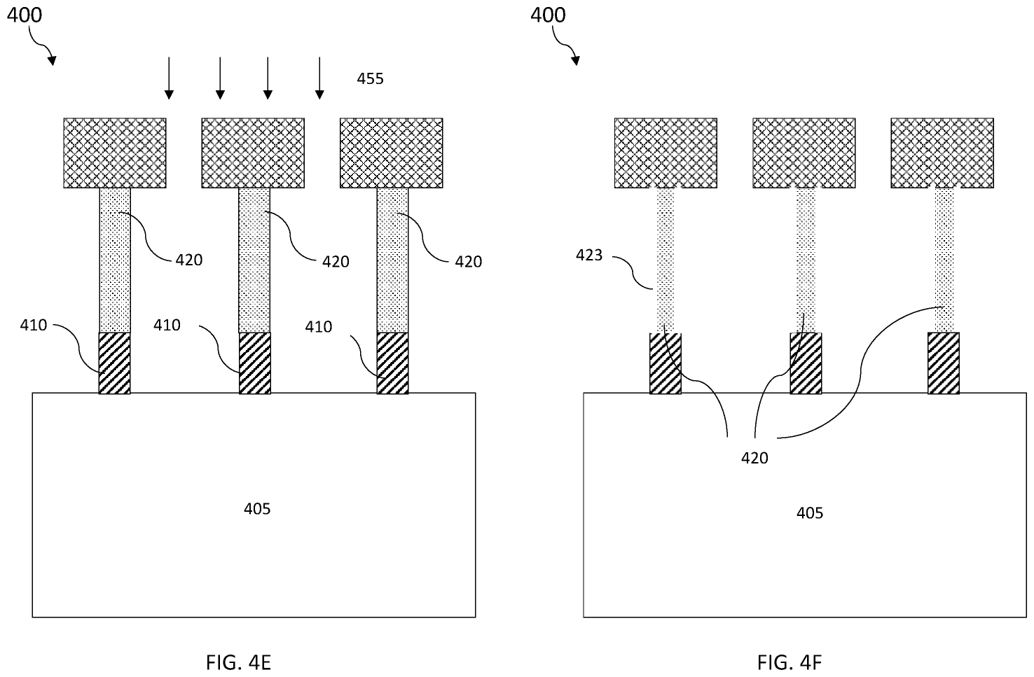

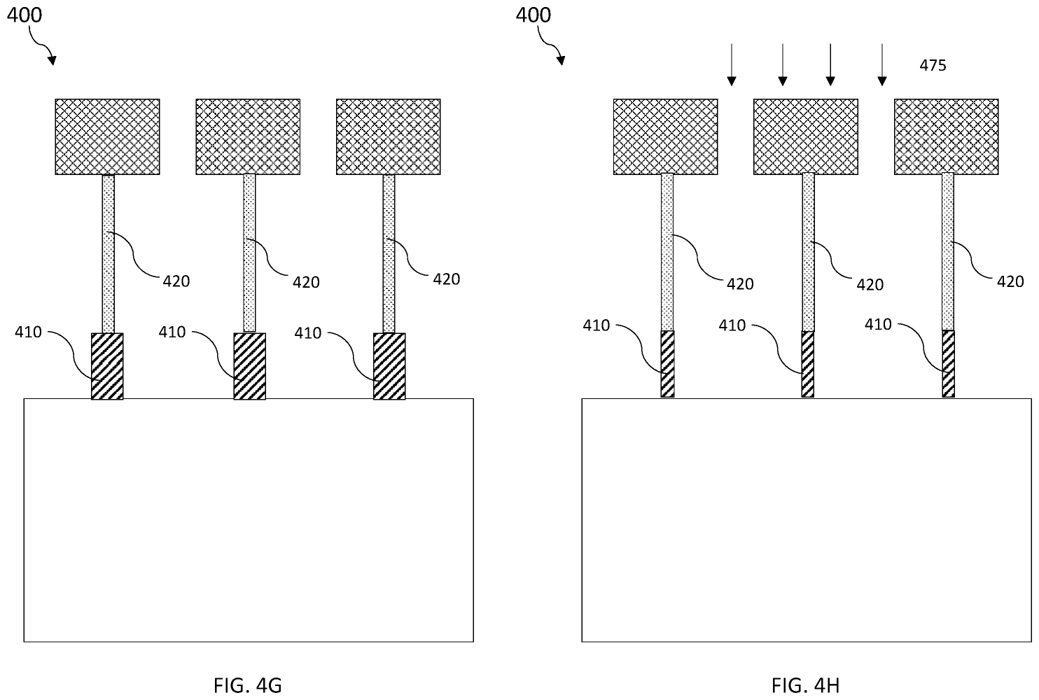

FIG. 3 illustrates a flow chart of a method 300 for fabricating a semiconductor device, in accordance with some embodiments. It is noted that the method 300 is merely an example and is not intended to limit the present disclosure. Accordingly, it is understood that additional operations may be provided before, during, and after the method 300 of FIG. 3, that any operation may be omitted, and that some other operations may only be briefly described herein. In various embodiments, operations of the method 300 may be associated with cross-sectional views of example structures at various fabrication stages as shown in FIGS. 4A to 4H, which will be discussed in further detail below. It should be understood that the structure, shown in FIGS. 4A to 4H, may include a number of other structures, while remaining within the scope of the present disclosure.

In brief overview, the method 300 starts with operation 302 of forming a first hardmask layer over a metallic layer and forming a second hardmask layer over the first hardmask layer. The method 300 continues to operation 304 of patterning the first hardmask layer through the second hardmask layer. The method 300 can proceed to operation 306 of oxidizing a sidewall of the first hardmask layer. The method 300 can proceed to operation 308 of removing the oxidized sidewall of the first hardmask layer to trim the first hardmask layer. The method 300 can proceed to operation 310 of etching the metallic layer using the trimmed first hardmask layer as a mask. The method 300 can proceed to operation 312 of further oxidizing the sidewall of the first hardmask layer. The method 300 can proceed to operation 314 of removing the oxidized sidewall of the first hardmask layer to further trim the first hardmask layer. The method 300 can proceed to operation 316 of etching the metallic layer using the further trimmed first hardmask layer as a mask.

Corresponding to operation 302 of FIG. 3, FIG. 4A is a cross-sectional view of a structure 400 in which a first hardmask layer 420 is formed over a metallic layer 410, and a second hardmask layer 430 is formed over the first hardmask layer 420. The metallic layer 410, formed of one or more metal materials, may be formed over a substrate 405. The metallic layer 410 may serve as a target to be patterned based on a pattern formed in the second hardmask layer 430. The pattern in the second hardmask layer 430 can be transferred to the metallic layer 410 (e.g., to form a number of patterned segments) through the first hardmask layer 420 that is later trimmed to have a shrunken dimension. The patterned segments of the metallic layer 410 may operatively serve as access lines or interconnect structures of the structure 400, respectively.

In some embodiments, the metal materials (of the metallic layer 410) can include at least one of: ruthenium (Ru), copper (Cu), aluminum (Al), and titanium (Ti). However, it should be understood that the metallic layer 410 can be any of various compound materials that include the above-listed metal material, while remaining within the scope of the present disclosure. In some embodiments, the substrate 405 may be a semiconductor substrate, such as a bulk semiconductor, a semiconductor-on-insulator (SOI) substrate, or the like, which may be doped (e.g., with a p-type or an n-type dopant) or undoped. The substrate 405 may be a wafer, such as a silicon wafer. Other substrates, such as a multi-layered or gradient substrate may also be used. In some embodiments, the first hardmask layer 420 may include a dielectric material selected from the group consisting of: silicon nitride (SiN), silicon oxynitride (SiON), silicon nitride-based material, and combinations thereof, and the second hardmask layer 430 may include a metal oxide material such as, for example, zirconium (Zr) oxide, titanium (Ti) oxide, tungsten (W) oxide, aluminum (Al) oxide, or combinations thereof. In some other embodiments, the second hardmask layer 430 may include a metal nitride, a metal carbide, or combinations thereof.

Corresponding to operation 304 of FIG. 3, FIG. 4B is a cross-sectional view of the structure 400 in which the first hardmask layer 420 is patterned through the second hardmask layer 430. In some embodiments, the first hardmask layer 420 may be patterned through performing a directional or anisotropic etching process 435. For example, through the anisotropic etching process 435, the pattern formed in the second hardmask layer 430 can be transferred to the underlying first hardmask layer 420. In some embodiments, the anisotropic etching process 435 may be stopped upon the metallic layer 410 being exposed.

In the example where the first hardmask layer 420 is formed of SiN, the anisotropic etching process 435 may include flowing CH₃F gas with ions (or reactive ions) in presence. Further, the anisotropic etching process 435 may be a reactive ion etching (RIE) process. In general, the RIE process entails exposing a workpiece to a reactive plasma that may include gases that generate species, such as fluorine, carbon, hydrogen, and molecules and radicals of the combination of these elements. Energetic ion bombardment by species extracted from the RIE plasma can generally have a trajectory normal to a surface of the workpiece that horizontal surfaces are subject to the ion bombardment to the exclusion of other surfaces such as vertical surfaces. As a non-limiting example, a high-frequency power of about 345 Watts and a low-frequency power of about 100 Watts, a pressure of about 30 millitorr, and a flow of the etchant gas (CH₃F) of about 50 sccm may be used in the anisotropic etching process 435.

Corresponding to operation 306 of FIG. 3, FIG. 4C is a cross-sectional view of the structure 400 in which a sidewall of the first hardmask layer 420 is oxidized. In some embodiments, the sidewall of the first hardmask layer 420 may be partially formed as an oxidized layer 421 through an oxidation process. The oxidized layer 421 may surround an outer circumference of the first hardmask layer 420 that has not been oxidized and may inwardly extend from the intact (or original) sidewall of the first hardmask layer 420 into a core of the first hardmask layer 420. In some embodiments, such an oxidation process can be performed in the same chamber where operation 304 was performed by flowing oxygen. Alternatively or additionally, the oxidation process can be performed in a vacuum chamber of a gas chemical etch system that is configured to later perform a removal process (e.g., operation 308).

Corresponding to operation 308 of FIG. 3, FIG. 4D is a cross-sectional view of the structure 400 in which the oxidized sidewall of the first hardmask layer 420 (or the oxidized layer 421) is removed to trim the first hardmask layer 420. Depending on a thickness or extension of the oxidized layer 421, the first hardmask layer 420 may be trimmed to have a smaller dimension. For example, prior to the oxidation process, the first hardmask layer 420 may have a diameter of about 200 nanometers (nm) and the oxidized layer 421 may have a thickness of about 2 nm. After removing the oxidized layer 421, the first hardmask layer 420 may be trimmed to have a diameter of about 196 nm. In some embodiments, an iteration of operations 306 and 308 may be repeatedly performed until the dimension of the first hardmask layer 420 reaches a desired value.

In some embodiments, the removal process of the oxidized layer 421 may include an isotropic etching process with a sufficient etching selectivity between the oxidized layer 421 and other materials, e.g., the materials of the second hardmask layer 430, the first hardmask layer 420, and the metallic layer 410. As such, while removing the oxidized layer 421, the second hardmask layer 430 may remain substantially intact. For example, the removal process may include flowing an ion-free etchant gas. As a non-limiting example, a radio frequency-power of about 0 Watts, a pressure of about 200 millitorr, and a flow of the etchant gas (HF) of about 50 sccm may be used in the removal process.

Corresponding to operation 310 of FIG. 3, FIG. 4E is a cross-sectional view of the structure 400 in which the metallic layer 410 is patterned through the trimmed first hardmask layer 420. In some embodiments, the metallic layer 410 may be patterned through performing a directional or anisotropic etching process 455. For example, through the anisotropic etching process 455, the pattern formed in the trimmed first hardmask layer 420 can be transferred to the underlying metallic layer 410. For example, the first hardmask layer 420 is trimmed to have a smaller dimension with respect to the pattern formed in the second hardmask layer 430, and thus, the metallic layer 410 can follow the dimension of the trimmed first hardmask layer 420 to form a number of metal segments with a shrunk dimension. In some embodiments, the anisotropic etching process 455 may be stopped upon the substrate 405 being exposed.

In the example where the metallic layer 410 is formed of Ru, the anisotropic etching process 455 may include flowing Cl₂ gas with ions (or reactive ions) in presence. Further, the anisotropic etching process 455 may be a reactive ion etching (RIE) process. As a non-limiting example, a high-frequency power of about 1200 Watts and a low-frequency power of about 100 Watts, a pressure of about 50 millitorr, and a flow of the etchant gas (Cl₂) of about 60˜70 sccm may be used in the anisotropic etching process 455.

Corresponding to operation 312 of FIG. 3, FIG. 4F is a cross-sectional view of the structure 400 in which a sidewall of the trimmed first hardmask layer 420 is oxidized. In some embodiments, the sidewall of the trimmed first hardmask layer 420 may be partially formed as an oxidized layer 423 through an oxidation process. The oxidized layer 423 may surround an outer circumference of the trimmed first hardmask layer 420 that has not been oxidized and may inwardly extend from the intact (or original) sidewall of the trimmed first hardmask layer 420 into a core of the trimmed first hardmask layer 420. Alternatively stated, the oxidized layer 423 may be formed above the patterned metal segments of the metallic layer 410. In some embodiments, such an oxidation process can be performed in the same chamber where operation 304 was performed by flowing oxygen. Alternatively or additionally, the oxidation process can be performed in a vacuum chamber of a gas chemical etch system that is configured to later perform a removal process (e.g., operation 314).

Corresponding to operation 314 of FIG. 3, FIG. 4G is a cross-sectional view of the structure 400 in which the oxidized sidewall of the first hardmask layer 420 (or the oxidized layer 423) is removed to further trim the first hardmask layer 420. Depending on a thickness or extension of the oxidized layer 423, the first hardmask layer 420 may be further trimmed to have an even smaller dimension. For example, prior to the oxidation process, the trimmed first hardmask layer 420 may have a diameter of about 195 nanometers (nm) and the oxidized layer 423 may have a thickness of about 2 nm. After removing the oxidized layer 423, the first hardmask layer 420 may be further trimmed to have a diameter of about 192 nm.

In some embodiments, the removal process of the oxidized layer 423 may include an isotropic etching process with a sufficient etching selectivity between the oxidized layer 423 and other materials, e.g., the materials of the second hardmask layer 430, the first hardmask layer 420, and the metallic layer 410. As such, while removing the oxidized layer 423, the second hardmask layer 430 may remain substantially intact. For example, the removal process may include flowing an ion-free etchant gas. As a non-limiting example, a radio frequency-power of about 0 Watts, a pressure of about 200 millitorr, and a flow of the etchant gas (HF) of about 50 sccm may be used in the removal process.

Corresponding to operation 316 of FIG. 3, FIG. 4H is a cross-sectional view of the structure 400 in which the metallic layer 410 is further patterned through the trimmed first hardmask layer 420. In some embodiments, the metallic layer 410 may be patterned through performing a directional or anisotropic etching process 475. For example, through the anisotropic etching process 475, the pattern formed in the trimmed first hardmask layer 420 can be transferred to the underlying metallic layer 410 (or metal segments). For example, the first hardmask layer 420 is trimmed to have a further smaller dimension with respect to the pattern formed in the second hardmask layer 430, and thus, the metallic layer 410 can follow the dimension of the trimmed first hardmask layer 420 to form a number of metal segments with a further shrunk dimension. In some embodiments, after the metallic layer 410 has been patterned to have a desired profile, the remaining portions of the second hardmask layer 430 and the first hardmask layer 420 are removed.

In the example where the metallic layer 410 is formed of Ru, the anisotropic etching process 425 may include flowing Cl₂ gas with ions (or reactive ions) in presence. Further, the anisotropic etching process 475 may be a reactive ion etching (RIE) process. As a non-limiting example, a high-frequency power of about 1200 Watts and a low-frequency power of about 100 Watts, a pressure of about 50 millitorr, and a flow of the etchant gas (Cl₂) of about 60˜70 sccm may be used in the anisotropic etching process 475.

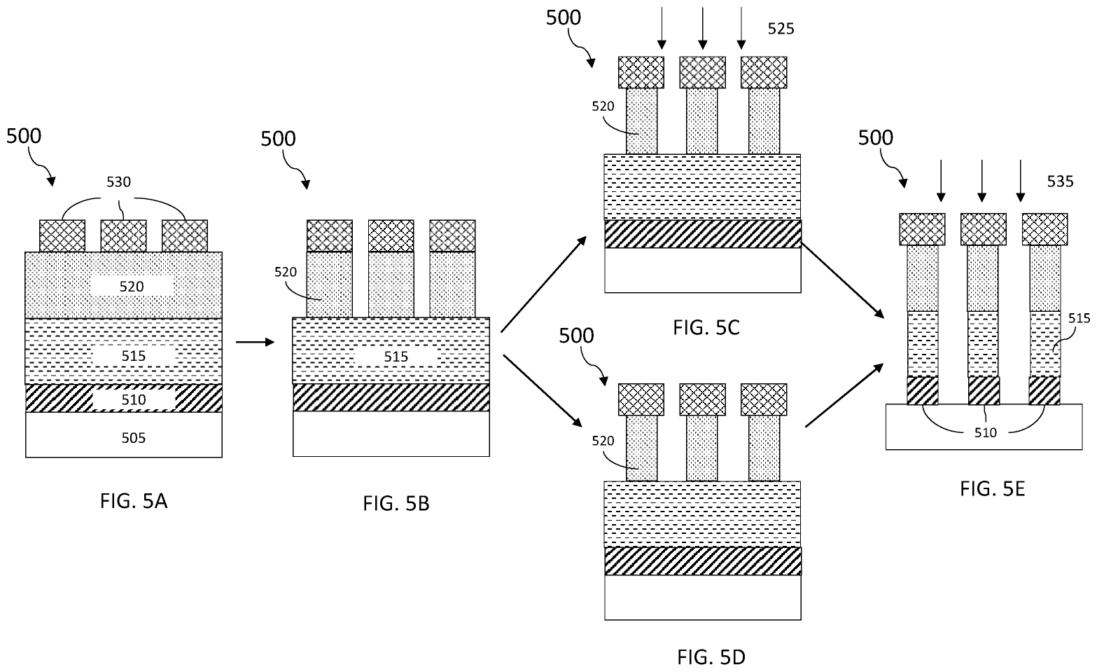

FIGS. 5A, 5B, 5C, 5D, and 5E illustrate cross-sectional views of a structure 500, made by at least some of the operations of the method 100 (FIG. 1) or 300 (FIG. 3), at various fabrication stages, respectively. The structure 500 is substantially similar to the structures 200 and 400 except that the structure 500 includes an organic hardmask layer, and thus, the following discussion of FIGS. 5A-5E will be focused on the difference. For example, in FIG. 5A, the structure 500 includes a substate 505 sequentially overlaid by a metallic layer 510, an organic hardmask layer 515, a first hardmask layer 520, and a second hardmask layer 530 including a pattern. The organic hardmask layer 515 may be or include an amorphous carbon layer (ACL) or an organic under layer (ODL) such as, for example, CH₄ and/or C₂H₂. In FIG. 5B, the pattern in the second hardmask layer 530 is transferred to the first hardmask layer 520 through an RIE process, with some portions of the top surface of the organic hardmask layer 515 being exposed. Since the underlying metallic layer 510 is covered by the organic hardmask layer 515, the first hardmask layer 520 can be trimmed by either an ion-based RIE process (e.g., 525 in FIG. 5C) or an oxidation process followed by flowing an ion-free etchant gas similar to operations 106-108 or operations 306-308 (e.g., FIG. 5D). After the first hardmask layer 520 is trimmed, the metallic layer 510 (together with the organic hardmask layer 515) can be patterned through another RIE process 535 using the trimmed first hardmask layer 520 as a mask.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method for fabricating semiconductor devices, comprising:
sequentially forming at least a first hardmask layer and a second hardmask layer over a metallic layer;
patterning the second hardmask layer and then the first hardmask layer;
oxidizing a sidewall of the patterned first hardmask layer;
removing the oxidized sidewall of the first hardmask layer; and
etching the metallic layer using a remaining portion of the first hardmask layer as a mask.

2. The method of claim 1, wherein the step of removing the oxidized sidewall of the first hardmask layer comprises flowing an etchant gas.

3. The method of claim 2, wherein the step of removing the oxidized sidewall of the first hardmask layer is ion-free.

4. The method of claim 1, wherein the first hardmask layer comprises a dielectric material selected from the group consisting of: silicon nitride (SiN), silicon oxynitride (SiON), silicon nitride-based material, and combinations thereof, and the second hardmask layer comprises a metal oxide material.

5. The method of claim 1, prior to etching the metallic layer, further comprising repeating the step of oxidizing a sidewall of the patterned first hardmask layer and the step of removing the oxidized sidewall of the first hardmask layer.

6. The method of claim 1, subsequently to etching the metallic layer, further comprising repeating the step of oxidizing a sidewall of the patterned first hardmask layer and the step of removing the oxidized sidewall of the first hardmask layer.

7. The method of claim 6, subsequently to repeating the step of oxidizing a sidewall of the patterned first hardmask layer and the step of removing the oxidized sidewall of the first hardmask layer, further comprising etching again the metallic layer.

8. The method of claim 1, further comprising:
prior to forming the first hardmask layer, covering the metallic layer with a third hardmask layer comprising an organic dielectric.

9. The method of claim 1, wherein the remaining portion of the first hardmask layer has a first dimension and the patterned second hardmask layer has a second dimension, and wherein the first dimension is smaller than the second dimension.

10. A method for fabricating semiconductor devices, comprising:
forming a first hardmask layer over a metallic layer;
forming a second hardmask layer over the first hardmask layer;
performing a first etching process to pattern the first hardmask layer through the second hardmask layer, thereby exposing a sidewall of the patterned first hardmask layer;
removing a portion of the exposed sidewall of the first hardmask layer through flowing an ion-free etchant gas; and
performing a second etching process using a remaining portion of the first hardmask layer as a mask to pattern the metallic layer.

11. The method of claim 10, wherein the removed portion of the exposed sidewall comprises an oxidized dielectric material.

12. The method of claim 10, wherein the first hardmask layer comprises a dielectric material selected from the group consisting of: silicon nitride (SiN), silicon oxynitride (SiON), silicon nitride-based material, and combinations thereof, and the second hardmask layer comprises a metal oxide material.

13. The method of claim 10, prior to performing the second etching process, further comprising repeating the step of removing a portion of the exposed sidewall of the first hardmask layer.

14. The method of claim 10, subsequently to performing the second etching process, further comprising repeating the step of removing a portion of the exposed sidewall of the first hardmask layer.

15. The method of claim 14, subsequently to repeating the step of removing a portion of the exposed sidewall of the first hardmask layer, further comprising performing a third etching process on the metallic layer.

16. The method of claim 10, further comprising:
prior to forming the first hardmask layer, covering the metallic layer with a third hardmask layer comprising an organic dielectric.

17. The method of claim 10, wherein the remaining portion of the first hardmask layer has a first dimension and the patterned second hardmask layer has a second dimension, and wherein the first dimension is smaller than the second dimension.

18. A method for fabricating semiconductor devices, comprising:
forming a first hardmask layer over a metallic layer;
forming a second hardmask layer over the first hardmask layer;
performing a first etching process to pattern the first hardmask layer through the second hardmask layer;
oxidizing a sidewall of the patterned first hardmask layer;
removing the oxidized sidewall of the first hardmask layer through flowing an ion-free etchant gas; and
performing a second etching process using a remaining portion of the first hardmask layer as a mask to pattern the metallic layer.

19. The method of claim 18, wherein the first hardmask layer comprises a dielectric material selected from the group consisting of: silicon nitride (SiN), silicon oxynitride (SiON), silicon nitride-based material, and combinations thereof, and the second hardmask layer comprises a metal oxide material.

20. The method of claim 18, wherein the remaining portion of the first hardmask layer has a first dimension and the patterned second hardmask layer has a second dimension, and wherein the first dimension is smaller than the second dimension.
